(19) United States
(12) Patent Application Publication
(10) Pub. No.: US 2006/0216408 A1
(43) Pub. Date: Sep. 28, 2006

(54) Performance of radiation transfered electronic devices

(75) Inventors: Michael L. Boroson, Rochester, NY (US); Kelvin Nguyen, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/091,428

(22) Filed: Mar. 28, 2005

(51) Int. Cl. B05D 5/12

(52) U.S. Cl. 427/66

(57) ABSTRACT

In a method of making a device including forming an organic layer over a substrate, includes providing a donor element having top and bottom surfaces and coating the top surface of the donor element with organic material; moving the coated donor element to a transfer position in relation to the substrate in a controlled environment; and selecting a pressure difference at the transfer position between the top and bottom surfaces of the donor element to maintain a spaced position between the top surface of the donor element and the substrate wherein the selected pressure difference is such that the performance of the device is within an acceptable range.

### CROSS-REFERENCE TO RELATED APPLICATION

Reference is made to commonly assigned U.S. Patent Application commonly assigned U.S. patent application Ser. No. 10/855,719 filed May 27, 2004, entitled “Linear Laser Light Beam for Making OLEDS” by Kay et al, the disclosure of which is incorporated herein by reference.

### FIELD OF THE INVENTION

The present invention relates to electronic devices, such as organic light-emitting diodes (OLED), organic thin film transistors (OTFT), and particularly to transferring organic material from a donor element to form one or more organic layers in such devices.

### BACKGROUND OF THE INVENTION

Electronic devices, such as organic light-emitting diodes (OLED) and organic thin film transistors (OTFT) comprise organic materials for at least some of their performance. Contamination of these organic materials can have detrimental effects on the performance of the electronic devices in which they are incorporated. For example, it is well known that low levels of contamination can significantly decrease the operational lifetime of OLED devices.

In color or full-color organic electroluminescent (EL) displays (also known as organic light-emitting diode devices, or OLED devices) having an array of colored pixels such as red, green, and blue color pixels (commonly referred to as RGB pixels), precision patterning of the color-producing organic EL media are required to produce the RGB pixels. The basic OLED device has in common an anode, a cathode, and an organic EL medium sandwiched between the anode and the cathode. The organic EL medium can consist of one or more layers of organic thin films, where one of the layers is primarily responsible for light generation or electroluminescence. This particular layer is generally referred to as the emissive layer or light-emitting layer of the organic EL medium. Other organic layers present in the organic EL medium can provide electronic transport functions primarily and are referred to as either the hole-transporting layer (for hole transport) or electron-transporting layer (for electron transport). In forming the RGB pixels in a full-color OLED display panel, it is necessary to devise a method to precisely pattern the emissive layer of the organic EL medium or the entire organic EL medium.

In commonly-assigned U.S. Pat. No. 5,937,272, Tang has taught a method of patterning multicolor pixels (e.g. red, green, blue subpixels) onto a thin-film-transistor (TFT) array substrate by vapor deposition of an EL material. Such EL material is deposited on a substrate in a selected pattern via the use of a donor coating on a support and an aperture mask.

Using an unpatterned donor sheet and a precision light source, such as a laser, is another method of radiation transfer. Such a method is disclosed by Littman in commonly-assigned U.S. Pat. No. 5,688,551, and in a series of patents by Wolk et al. (U.S. Pat. Nos. 6,114,088; 6,140,009; 6,214,520; and 6,221,553). Kay et al., in commonly-assigned U.S. Pat. No. 6,582,875, have described the use of a multichannel laser for the light source to accelerate the radiation thermal transfer process.

While this is a useful technique for manufacturing, EL devices that include organic layers prepared this way often suffer from decreased stability relative to EL devices with organic layers prepared in other ways, e.g. vapor deposition. There is a need to improve the stability of electroluminescent devices prepared using a radiation thermal transfer process.

Radiation thermal transfer is also a useful technique for patterning organic materials in other types of electronic devices. Devices such as OTFT, however, will also suffer decreased performance if contamination of the functional organic materials is not controlled when using the radiation thermal transfer process.

### SUMMARY OF THE INVENTION

It is therefore an object of the present invention to improve the performance of electronic devices prepared using a radiation thermal transfer process.

This object is achieved in a method of making a device including forming an organic layer over a substrate, comprising:

(a) providing a donor element having top and bottom surfaces and coating the top surface of the donor element with organic material;

(b) moving the coated donor element to a transfer position in relation to the substrate in a controlled environment; and

(c) selecting a pressure difference at the transfer position between the top and bottom surfaces of the donor element to maintain a spaced position between the top surface of the donor element and the substrate wherein the selected pressure difference is such that the performance of the device is within an acceptable range.

The present invention can improve performance of electronic devices, such as OLED devices, prepared using a radiation thermal transfer process with no loss in manufacturing efficiency.

### BRIEF DESCRIPTION OF THE DRAWINGS

FIG. 1 is a cross-sectional view of one embodiment of the apparatus used in this invention;

FIG. 2 is a cross-sectional view of one embodiment of the apparatus used in this invention with an open configuration;

FIG. 3 shows a cross-sectional view of one embodiment of the apparatus at the transfer position;

FIG. 4 shows a portion of one embodiment of the apparatus at the transfer position in greater detail and shows a means for supplying and maintaining pressure difference between different chambers;

FIG. 5 is a plot showing different environmental contamination conditions inside the vacuum chamber;

FIG. 6 shows pressure difference applied between the top and bottom surfaces of the donor element in second chamber according to the invention;

FIG. 7 shows a pressure difference dependence on the controlled environment;

FIG. 8 shows a cross-sectional view of a coated donor element;

FIG. 9 shows device performance vs. time from coating donor element to pressure difference has been applied; and

FIG. 10 shows device performance vs. time starting from when pressure difference has been applied to when the radiation transfer process has been completed.

Since device feature dimensions such as layer thicknesses are frequently in sub-micrometer ranges, the drawings are scaled for ease of visualization rather than dimensional accuracy.

### DETAILED DESCRIPTION OF THE INVENTION

The term “OLED device” or “organic light-emitting display” is used in its art-recognized meaning of a display device including organic light-emitting diodes as pixels. The term “OTFT device” or “organic thin film transistor” is used in its art-recognized meaning of a thin film transistor comprising organic electronic materials. A color OLED device emits light of at least one color. The term “multicolor” is employed to describe a display panel that is capable of emitting light of a different hue in different areas. In particular, it is employed to describe a display panel that is capable of displaying images of different colors. These areas are not necessarily contiguous. The term “full color” is commonly employed to describe multicolor display panels that are capable of emitting in the red, green, and blue regions of the visible spectrum and displaying images in any combination of hues. The red, green, and blue colors constitute the three primary colors from which all other colors can be generated by appropriate mixing. However, the use of additional colors to extend the color gamut of the device is possible. The term “hue” refers to the intensity profile of light emission within the visible spectrum, with different hues exhibiting visually discernible differences in color. The term “pixel” is employed in its art-recognized usage to designate an area of a display panel that can be stimulated to emit light independently of other areas. However, it is recognized that in full-color systems, several pixels of different colors will be used together to generate a broad range of colors, and a viewer may term such a group a single pixel.

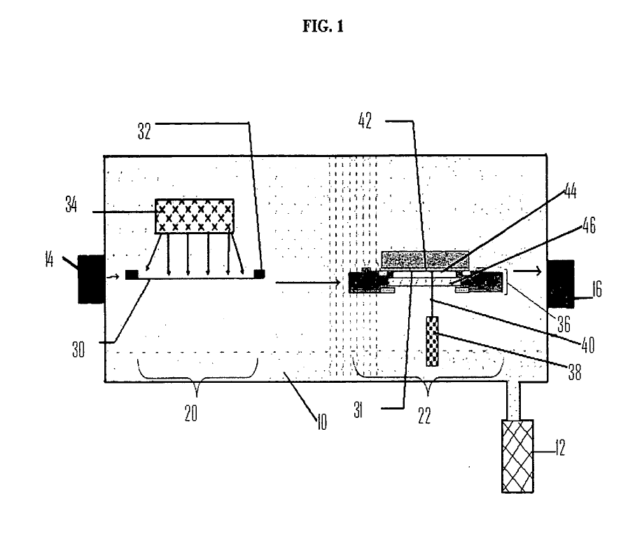

FIG. 1 is a cross-sectional representation of one embodiment of the present invention in which a donor element 30 is coated with organic material, and the transfer of the organic material to a substrate 42 is effected in the same evacuated chamber. For purposes of this disclosure, the term “substrate” shall refer to the supporting structure for receiving the organic material to be coated. This supporting structure can include an underlying support that may have one or more organic or inorganic layers. Vacuum coater 10 is an enclosed apparatus described herein that permits the donor element 30 to be coated by means such as vapor deposition, and the coated material to be subsequently transferred to the substrate 42 such as by radiation thermal transfer, under vacuum conditions. Vacuum coater 10 can include one chamber, or any number of chambers which can be connected by load locks or similarly acting apparatus such as tunnels or buffer chambers, whereby donor elements and substrates can be transported without exposure to non-vacuum conditions. The term “vacuum” is used herein to designate a pressure of 1 Torr or less. Vacuum coater 10 is held under vacuum by a vacuum pump 12. Vacuum coater 10 includes a load lock 14, which is used to load the chamber with donor element 30. Vacuum coater 10 also includes a load lock 16, which is used to unload a used coated donor element 31. Load locks 14 and 16 are means of introducing and removing materials from vacuum coater 10 without contaminating the conditions inside with the outside environment. The interior of vacuum coater 10 includes a coating station 20 and a transfer station 22. Coating station 20 is a location within vacuum coater 10 that permits a donor element 30 to be coated by means such as vapor deposition. Transfer station 22 is a location within vacuum coater 10 that facilitates the transfer of the coated material to the substrate 42, such as by thermal transfer.

Donor element 30 is introduced to vacuum coater 10 by means of load lock 14. Donor element 30 is an element that can accept an organic material by means such as vapor deposition or sputtering, and can subsequently transfer all or part of the organic material such as by thermal transfer. Donor element 30 can optionally be supported by a donor support 32. Donor element 30 is transferred by mechanical means to coating station 20. Coating station 20 includes a coating apparatus 34. Coating apparatus 34 can consist of any apparatus capable of coating the organic materials in a vacuum, including, but not limited to evaporation and sputtering. This can be, e.g., vapor deposition apparatus such as that described in commonly-assigned U.S. Pat. Nos. 6,237,529; 6,513,451 and 6,558,735, the disclosures of which are incorporated herein by reference, or any other apparatus capable of coating the organic materials in a vacuum. If multiple materials are to be coated in a layer, e.g. a host and a dopant material, the materials can be mixed together and deposited from a single source, or alternatively multiple sources can be used with different materials loaded in each source. Additionally, multiple sources can be used at separate times within vacuum coater 10 to coat separate layers on donor element 30 or on substrate 42, or can be used to coat additional donor elements 30. Coating apparatus 34 is activated (e.g., desired material is heated to vaporize it) and donor element 30 is coated evenly with material, rendering it into coated donor element 31. Coated donor element 31 is an element coated with one or more organic material layers that can subsequently be transferred in whole or in part such as by radiation thermal transfer.

Substrate 42 is introduced to vacuum coater 10 by means of load lock 16 and transferred by mechanical means to transfer apparatus 36. This can occur before, after, or during the introduction of donor element 30. Transfer apparatus 36 can consist of any apparatus capable of facilitating the transfer of organic materials on coated donor element 31 in a vacuum, in response to heat or radiation converted to heat. One example of transfer apparatus 36, its construction, and its means of operation with coated donor element 31 and substrate 42 have already been described in commonly-assigned U.S. Pat. No. 6,695,029; the disclosure of which is incorporated herein by reference. Transfer apparatus 36 is shown for convenience in the closed configuration, but it also has an open configuration in which coated donor element 31 and substrate 42 loading and unloading occurs.

Coated donor element 31 is transferred by mechanical means from coating station 20 to transfer station 22 and placed into a transfer position in a controlled environment within a first selected time, wherein the first selected time is such that the performance of the device is within an acceptable range. The term “acceptable range” refers to the performance of the device with respect to device requirements or specifications. The “acceptable range” will vary from application to application and from device type to device type. To one skilled in the art the “acceptable range” is determined to be the acceptable performance of the device relative to the performance requirements or specifications for that device.

Coated donor element 31 and substrate 42 are placed in a material transferring relationship, that is, the coated side of coated donor element 31 is placed in close contact with the receiving surface of substrate 42 and held in place by a means such as fluid pressure in a pressure chamber 44, as described in commonly-assigned U.S. Pat. No. 6,695,029. The selected pressure difference is such that the performance of the device is within an acceptable range. On the following description, after the substrate 42 and coated donor element 31 has been held in place together and a selected fluid pressure is applied, it is called a “transfer position” since the coated donor element 31 and substrate 42 are in a position ready to receive radiation.

Coated donor element 31 can then be irradiated through a transparent portion 46 by applied radiation, such as by a laser beam 40 from a laser 38. The irradiation of coated donor element 31 in a pattern causes the transfer of organic material from coated donor element 31 to substrate 42, as described in commonly-assigned U.S. Pat. No. 6,695,029. The second selected time between applying the selected pressure difference to transferring organic material from coated donor element 31 to substrate 42 is selected such that the performance of the device is within an acceptable range.

Substrate 42 can be treated with one or more layers of materials (e.g. an anode material, a cathode material, a hole-transport material, etc.) before undergoing the method herein. Substrate 42 can further be treated with one or more layers of materials (e.g. an anode material, a cathode material, an electron-transport material, etc.) and with protective layers after undergoing the method herein. These treatments can be effected outside of vacuum coater 10 or inside vacuum coater 10 at coating station 20. After irradiation is complete, transfer apparatus 36 is opened and coated donor element 31 and substrate 42 can be removed via load lock 16.

Alternatively, the embodiment in FIG. 1 can be used to transfer more than one layer to the substrate 42 in different patternwise transfers. In this method, a plurality of donor elements 30 are introduced to vacuum coater 10 such that each coating station 20 is provided with a unique donor element 30. Each donor element 30 is coated evenly with organic material by its respective coating apparatus, thus rendering each into a unique coated donor element 31. Coated donor element 31 is transferred by mechanical means from coating station 20 to transfer station 22 in a controlled environment within a first selected time, wherein the first selected time is such that the performance of the device is within an acceptable range. Substrate 42 is introduced to vacuum coater 10 by means of load lock 16 and transferred by mechanical means to transfer apparatus 36. This can occur before, after, or during the introduction of donor element 30. Transfer apparatus 36 is shown for convenience in the closed configuration, but it also has an open configuration in which the coated donor element and substrate loading and unloading occurs. Coated donor element 31 and substrate 42 are placed into a transfer position with a pressure difference selected such that the performance of the device is within an acceptable range. Coated donor element 31 is then irradiated through transparent portion 46 by applied radiation such as by laser beam 40 from laser 38. The irradiation of coated donor element 31 in a pattern causes the transfer of organic material from coated donor element 31 to substrate 42, as described in commonly-assigned U.S. Pat. No. 6,695,029. The second selected time between applying the selected pressure difference and transferring coated material from coated donor element 31 to substrate 42 is selected such that the performance of the device is within an acceptable range.

After irradiation is complete, transfer apparatus 36 is opened and coated donor element 31 can be removed via load lock 16. The second coated donor element 31 is transferred by mechanical means to transfer station 22 and placed into a transfer position within a first selected time and the transfer process is repeated. The transfer process in the several transfer operations can follow the same pattern of irradiation, or each transfer can be effected using a different pattern of laser irradiation.

It will be clear to those skilled in the art that this process can be used in the manufacture of a full-color display device, such as a full-color OLED device. Such devices generally are comprised of red, green, and blue subpixels. A vacuum coater 10 with three coating stations can be used to prepare the required coated donor element 31. Each coated donor element 31 is prepared with a coating of a different organic material layer to reflect the desired output color or hue, that is with either a red, blue, or green emissive layer. Each coated donor element 31 is transferred sequentially by mechanical means from its respective coating station to transfer station 22 within a first selected time, wherein the first selected time is such that the performance of the OLED device is within an acceptable range. Coated donor element 31 and substrate 42 are placed into a transfer position with a pressure difference selected such that the performance of the OLED device is within an acceptable range. Coated donor element 31 is then irradiated through transparent portion 46 by applied radiation such as by laser beam 40 from laser 38. The irradiation of coated donor element 31 in a pattern causes the transfer of organic material from coated donor element 31 to substrate 42, as described in commonly-assigned U.S. Pat. No. 6,695,029. The second selected time between applying the selected pressure difference and transferring organic material from coated donor element 31 to substrate 42 is selected such that the performance of the OLED device is within an acceptable range. For example, the red emissive material is transferred patternwise to the red subpixels, the blue emissive material is transferred patternwise to the blue subpixels, and the green emissive material is transferred patternwise to the green subpixels. Substrate 42 can be treated with one or more layers of materials (e.g. an anode material, a cathode material, a hole-transport material, etc.) before undergoing the method herein. Substrate 42 can further be treated with one or more layers of materials (e.g. an anode material, a cathode material, an electron-transport material, etc.) and with protective layers after undergoing the method herein. These treatments can be effected outside of vacuum coater 10 or inside vacuum coater 10 at coating station 20.

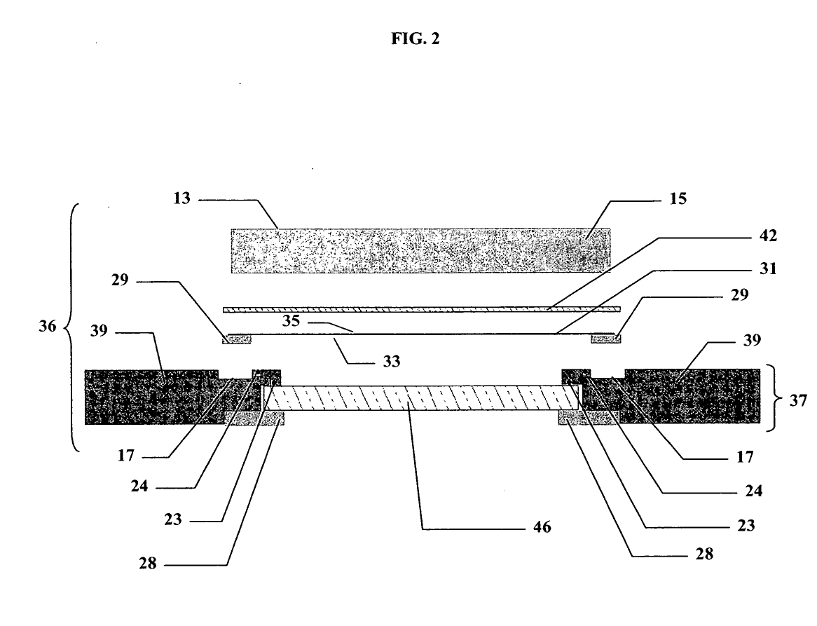

FIG. 2 is a cross-sectional view of one embodiment of the transfer apparatus 36 used in this invention with an open configuration. A first fixture 37 includes base plate 39 which, in this particular example, is an open rectangular plate that has been machined for the features to be described here. First fixture 37 is either attached to or a portion of a chamber such that at least a portion of the top side of first fixture 37 is inside the chamber. The chamber is called a vacuum chamber when the pressure inside the chamber is controlled to 1 Torr or less and called a controlled environment chamber when the pressure inside the chamber is greater than 1 Torr and the H₂O level, O₂ level, contaminant level or anything else that can reduce the performance of the device is not presented or presented at low levels inside the chamber. Both vacuum chambers and controlled environment chambers as described here provide controlled environments for making devices.

A base plate 39 contacts coated donor element 31 and can further accommodate coated donor element 31 mounted to a rigid frame 29. Coated donor element 31 has a top surface 35 coated with organic material and a bottom surface 33 that is uncoated. Fitted into base plate 39 is transparent portion 46, which can be in the form of a plate as depicted here or other convenient shape. Transparent portion 46 is formed of a material that is transparent to radiation of a predetermined portion of the spectrum and therefore permits the transmission of such radiation. Transparent portion 46 fits into base plate 39 and compresses a gasket 23, which fits into a slot that has been machined for it. Transparent portion 46 is held in base plate 39 by means of a retaining clamp 28, which is held to base plate 39 by means of screws or other fasteners (not shown). Transparent portion 46, gasket 23, and base plate 39 form an airtight seal. An airtight seal is defined herein as having no fluid leaks or having a sufficiently low leak rate as to not adversely affect the controlled environmental conditions within the vacuum chamber. Base plate 39 has another machined slot, which holds a gasket 24.

A second fixture 13 includes a plate 15 which, when engaged with first fixture 37 in a manner that will become apparent, clamps substrate 42 and coated donor element 31 to compress gasket 24 and to create an airtight chamber between bottom surface 33 of coated donor element 31 and transparent portion 46. Plate 15 is made of a rigid material, such as steel or rigid plastic, and is preferably flat to within the focal depth of a radiation source.

The open relationship of the first and second fixtures in FIG. 2 facilitates moving of coated donor element 31 and substrate 42 into and out of apparatus 36. Coated donor element 31 is placed between the fixtures in such a way that it will be supported by first fixture 37. Substrate 42 is placed between coated donor element 31 and second fixture 13. Since coated donor element 31 can be formed from a flexible support, rigid frame 29 can optionally be used as a support for the loading and unloading of sheets of coated donor element 31. In the case of the use of rigid frame 29, base plate 39 will include a machined slot 17 for receiving rigid frame 29.

Transparent portion 46 is a material transparent to the impinging radiation and structurally sufficient to withstand a pressure of at least 1 atmosphere between opposing sides. One example is an optical BK-7 glass made by Schott Glass Technologies, Inc., which is prepared to be optically clear to laser light. The thickness of transparent portion 46 is determined by its material properties, the pressure difference across transparent portion 46, and the overall exposed area.

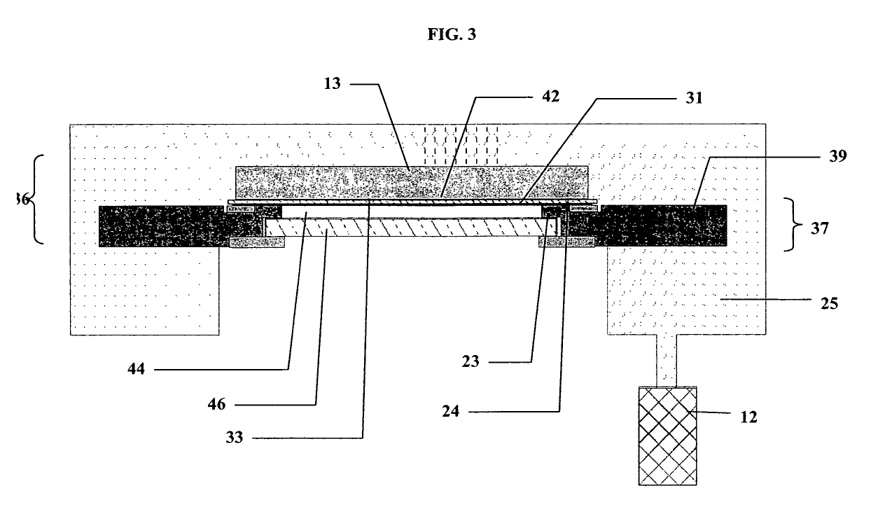

FIG. 3 shows a cross-sectional view of one embodiment of the transfer apparatus 36 in a controlled environment chamber.

First fixture 37 and second fixture 13 are aligned with each other so that they engage and provide pressure along the perimeter of pressure chamber 44, thus clamping substrate 42 and coated donor element 31, compressing gasket 24, and creating an airtight seal. Together with the airtight seal formed by base plate 39 with gasket 23 and transparent plate 46, pressure chamber 44 is formed to allow pressure difference to be provided between bottom surface 33 and top surface 35 of coated donor element 31. Second fixture 13 provides a flat surface that, in the case of irradiation by a radiation source, locates an appropriate radiation-absorbing portion of coated donor element 31 within the focal depth of the radiation source. The vacuum chamber is constructed either in such a way as to enclose coated donor element 31 and substrate 42 while leaving transparent portion 46 unenclosed in a controlled environment 25 or everything can be enclosed in controlled environment 25. In this embodiment controlled environment 25 is a vacuum chamber kept under vacuum by vacuum pump 12. In an alternative embodiment controlled environment 25 may be a dry inert environment such that the H₂O level, O₂ level, contaminant level or anything else that can reduce the performance of the device is not presented or presented at low levels inside the chamber.

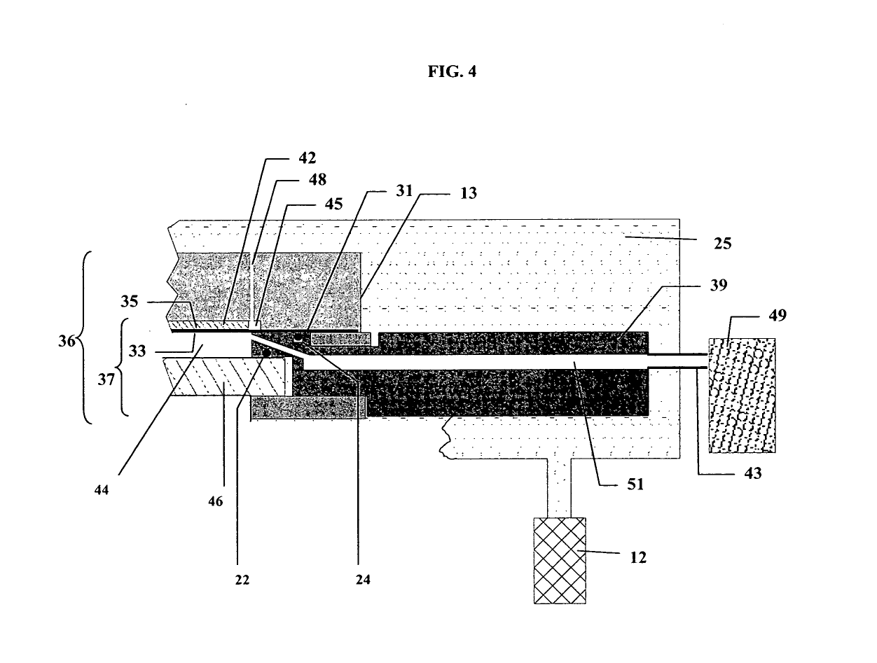

FIG. 4 shows a portion of one embodiment of the transfer apparatus 36 in greater detail, and shows a means for supplying fluid and maintaining pressure difference between top surface 35 and bottom surface 33 of coated donor element 31. One or more fluid inlets 43 are formed into base plate 39. They allow the introduction of fluid into a fluid passage 51, which conveys it to a pressure chamber 44. Fluid inlets 43 can include a means of connection to an external fluid supply 49. The pressure differential between pressure chamber 44 (which applies pressure on the bottom surface 33 of coated donor element 31) and the controlled environment 25 (which applies pressure on the top surface 35 of coated donor element 31) causes the top surface 35 of coated donor element 31 to be pressed against the receiving surface of substrate 42. Plate 15 provides a flat surface to locate the appropriate radiation-absorbing portion of coated donor element 31 within the focal depth of the radiation source. The fluid for creating a pressure in pressure chamber 44 can be a gas (e.g. air, nitrogen, argon, helium), a liquid (e.g. water or a liquid fluorocarbon), a gas that liquefies under pressure (e.g. Freon), or a supercritical fluid (e.g. carbon dioxide). A gas is the preferred fluid. Nitrogen, argon, or air are most preferred fluids. It will be seen that the pressure of fluid in pressure chamber 44 allows a relationship of coated donor element 31 and substrate 42 relative to each other so that a position of direct contact or a controlled separation relative to each other is ensured. The pressure delivered to pressure chamber 44 is greater than the pressure in controlled environment 25. It is important to keep the pressure of fluid in pressure chamber 44 to a low level that is just enough to press the coated donor element 31 against the substrate 42. It has been found unexpectedly that high pressure difference between the top and bottom surfaces of coated donor element 31 decreases the performance of OLED devices make by radiation transfer.

Second fixture 13 includes a recessed pocket that accommodates substrate 42. Coated donor element 31 extends beyond substrate 42 and is clamped against gasket 24 by second fixture 13 when second fixture 13 engages with first fixture 37. This creates a first chamber 45 relative to the top surface 35 of coated donor element 31 and pressure chamber 44 relative to bottom surface 33 of coated donor element 31. One or more channels 48 are formed into second fixture 13 and are open to the controlled environment 25 in such a way that the airtight seal created at gasket 24 is not disrupted. When fluid pressure is applied to pressure chamber 44, coated donor element 31 is pressed against substrate 42 which, in turn, is pressed against plate 15. Channels 48 maintain controlled environmental pressure conditions on top surface 35 of coated donor element 31 and on substrate 42 in first chamber 45 while bottom surface 33 is under relatively greater pressure in pressure chamber 44, creating the pressure difference.

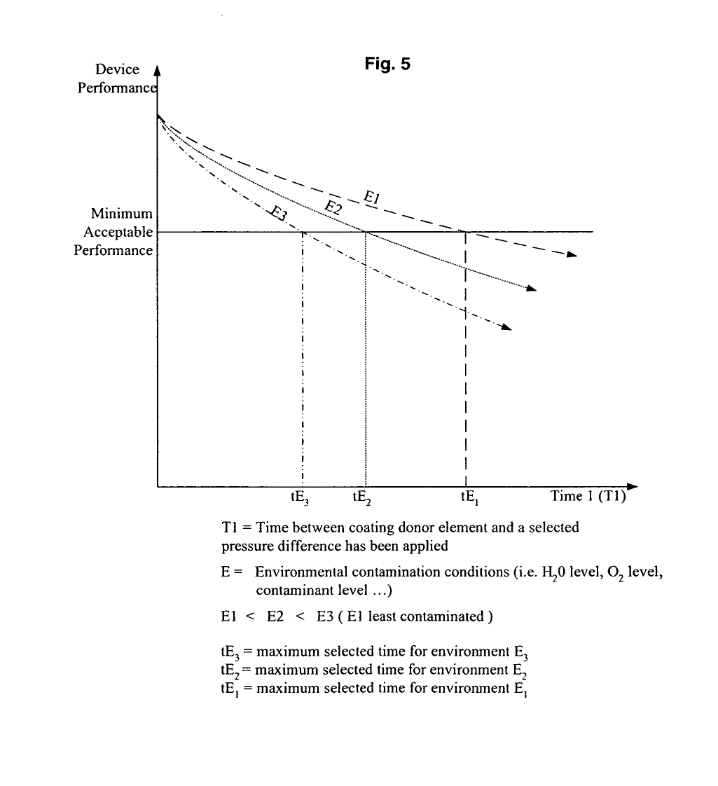

FIG. 5 shows one embodiment of the present invention for selecting a first selected time T1, such that device performance will be within an acceptable range, which for this embodiment is above a minimum acceptable performance. The figure shows different environmental contamination conditions inside the chamber and the effect of the environmental conditions on device performance due to the time that coated donor element is exposed to these different environmental conditions. E is the environmental contamination conditions where E1 shows the lowest contamination level, E2 shows the middle contamination level and E3 shows the highest contamination level inside the chamber. T1 is a first selected time starting from coating the donor element and ending when a selected pressure difference has been applied between the bottom and top surfaces of the coated donor element (transfer position). The figure shows that the higher the contamination level in the chamber, the faster the performance of the device formed by transfer of an organic layer from the coated donor element to the device substrate will decrease. For the higher contamination level E3 the maximum selected time t_{E3} must be shorter to achieve device performance above a minimum acceptable performance. In contrast, for the lowest contamination level E1, the slower the device performance will decrease and the maximum selected time t_{E1} may be much longer in that case. For extremely low contamination levels the maximum selected time may be very long. In this embodiment the first selected time T1 is selected based on the contamination level in the chamber such that the time is less than or equal to the time in which the device performance reaches the minimum acceptable performance level for that environmental contamination condition.

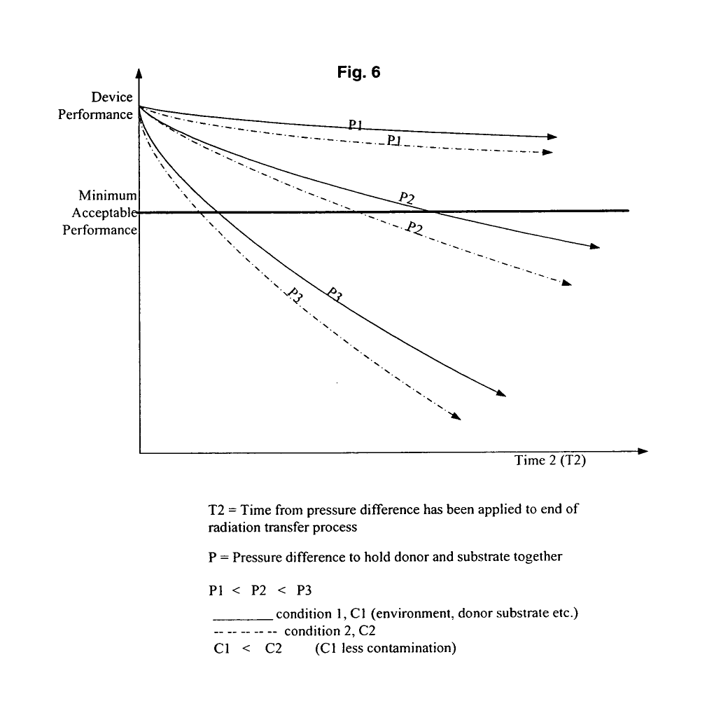

FIG. 6 shows another embodiment of the present invention for selecting a pressure difference P and a second selected time T2, such that device performance will be within an acceptable range which for this embodiment is above a minimum acceptable performance. The figure shows different pressure differences applied between the bottom and top surfaces of the coated donor element and the effect of the contamination conditions on device performance due to the time that coated donor element is exposed to the pressure difference and these different contamination conditions. In the figure different pressure differences are applied between the bottom and top surfaces of the coated donor element according to the invention. P is the pressure difference where P1<P2<P3. T2 is a second selected time starting from when pressure difference has been applied to when the radiation transfer process has been completed. Solid and broken lines represent two different contamination conditions C1 and C2 respectively. C1 condition is less contaminated than C2. The figure shows that the lower the pressure difference applied between the bottom and top surfaces of the coated donor element, the longer T2 may be to achieve device performance above a minimum acceptable performance. In contrast, the higher the pressure difference applied between the bottom and top surfaces of the coated donor element, the faster the device performance will decrease and T2 must be much shorter in that case. For example the maximum selected time t_{P2C2} at pressure difference P2 and contamination level C2 may be longer than the maximum selected time t_{P3C2} at pressure difference P3 and contamination level C2. In addition, when the contamination level is less contaminated (C1) either the pressure difference may be higher or the second selected time T2 may be longer, or both to achieve device performance above a minimum acceptable performance. For extremely low contamination levels, extremely low pressure differences, or both the maximum selected time may be very long. In this embodiment the pressure difference P and the second selected time T2 are selected based on the contamination level such that the time is less than or equal to the time in which the device performance reaches the minimum acceptable performance level for the selected pressure difference P and for that environmental contamination condition. Alternatively the selected pressure difference P may be selected to be low enough (for example pressure difference P1) that there is no time for which the device performance reaches the minimum acceptable performance level. In this alternative embodiment only the pressure difference must be selected to achieve device performance above a minimum acceptable performance.

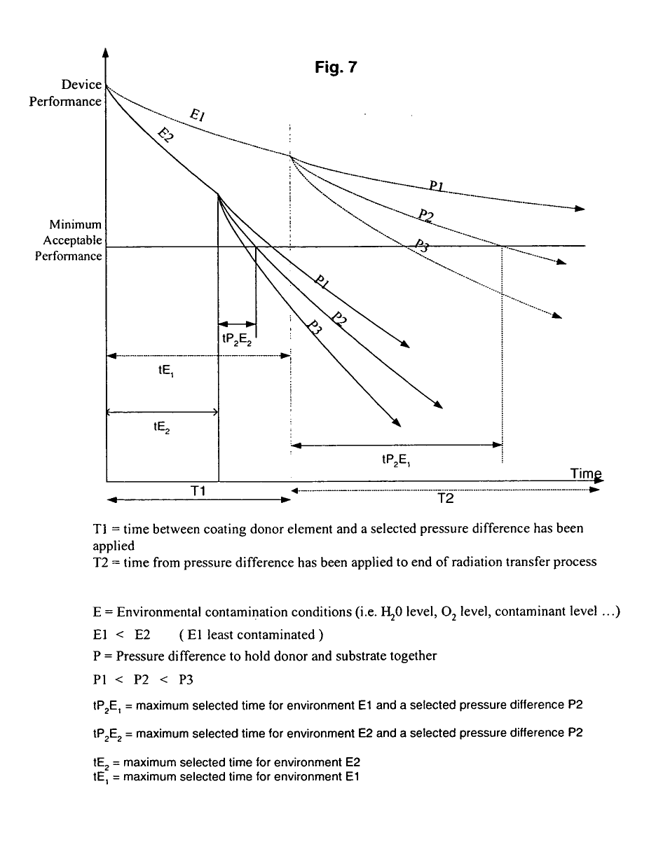

FIG. 7 shows another embodiment of the present invention for selecting a first selected time T1, a pressure difference P, and a second selected time T2, such that device performance will be within an acceptable range which in this embodiment is above a minimum acceptable performance. The figure shows both different environmental contamination conditions inside the chamber and different pressure differences applied between the bottom and top surfaces of the coated donor element. T1 is a first selected time starting from coating the donor element and ending when a selected pressure difference has been applied between the bottom and top surfaces of the coated donor element. E is the environmental contamination conditions where E1 shows the lowest contamination level and E2 shows the highest contamination level inside the chamber. The figure shows that the higher the contamination level, the faster the performance of the device formed by transfer of an organic layer from the coated donor element to the device substrate will decrease. For the higher contamination level E2, the maximum selected time t_{E2} is shorter to achieve device performance above minimum acceptable performance. In contrast, for the lower contamination level E1, the slower the device performance will decrease and the maximum selected time t_{E1} is much longer in that case. T2 is a second selected time starting from when pressure difference has been applied to when the radiation transfer process has been completed. P is the pressure difference where P1<P2<P3. The figure shows the lower the pressure difference applied between the bottom and top surfaces of the coated donor element, the longer T2 may be to achieve device performance above a minimum acceptable performance. In contrast, the higher the pressure difference applied between the bottom and top surfaces of the coated donor element, the faster the device performance will decrease and T2 must be much shorter in that case. For example the maximum selected time t_{P2E1} at pressure difference P2 and contamination level E1 may be longer than the maximum selected time t_{P3E1} at pressure difference P3 and contamination level E1. In addition, when the contamination level is less contaminated (E1) either the pressure difference may be higher or the second selected time T2 may be longer, or both to achieve device performance above a minimum acceptable performance. The curves of P1, P2 and P3 depend on the environmental contamination inside the chamber. For the higher contamination level E2, the maximum selected time t_{P2E2} is shorter to achieve device performance above minimum acceptable performance. In contrast, for the lower contamination level E1, the slower the device performance will decrease and the maximum selected time t_{P2E1} is much longer in that case.

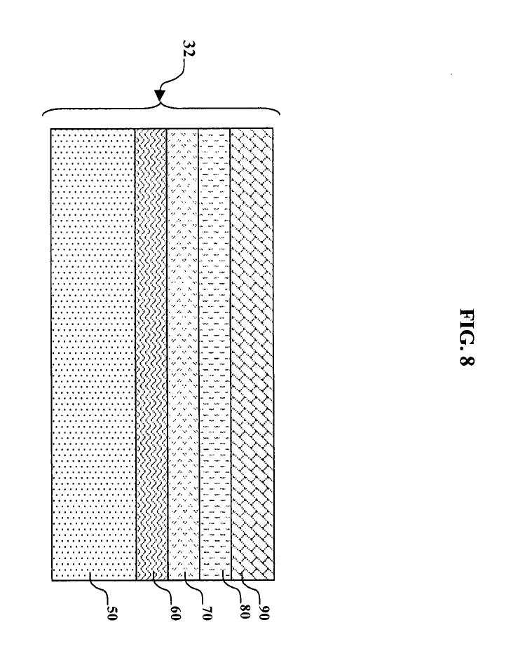

FIG. 8 now further describes one embodiment of the coated donor element 31 used in this invention, and the resulting OLED device. Coated donor element 31 includes a transparent support 50, a first metallic layer 70, a second metallic layer 80, and an organic layer 90. Coated donor element 31 can also optionally include an antireflection layer 60.

Transparent support 50 can be made of any of several materials which meet at least the following requirements: If the support material is a radiation-transmissive material, the incorporation into the support or onto a surface thereof, of a radiation-absorptive material can be advantageous to more effectively heat the donor support and to provide a correspondingly enhanced transfer of transferable organic emissive material from the support to the substrate, when using a flash of radiation from a suitable flash lamp or laser light from a suitable laser. In such a case, transparent support 50 is first uniformly coated with first metallic layer 70 capable of absorbing radiation in a predetermined portion of the spectrum to produce heat. First metallic layer 70 can be a metal such as Ag, Au, Be, Co, Cr, Cu, Fe, Ir, Mo, Nb, Ni, Pt, Rh, Ta, Pd, V, or W, or mixtures thereof. Preferred metals from this group are Be, Cr, V, Mo, Pt, or W, or mixtures thereof.

Antireflection layer 60 is an optional layer in coated donor element 31 and includes a material having the real portion of its index of refraction greater than 3.0. This includes materials such as silicon, germanium, and combinations thereof. Particularly useful combinations of antireflection layer 60 and first metallic layer 70 include silicon with chromium, and germanium with nickel. The use of an antireflection layer, and the process of matching an effective antireflection layer with a first metallic layer, has been described in commonly-assigned U.S. Pat. No. 6,790,594, the disclosure of which is herein incorporated by reference.

A second metallic layer 80 was coated on top of the first metallic layer 70 to react with moisture and/or oxygen on the surface of the first metallic layer 70. It is a desired feature to have no moisture and/or oxygen on the surface of first metallic layer 70 because moisture and/or oxygen can degrade organic layer 90 and therefore give poor device performance. Second metallic layer 80 includes a metal that is reactive towards moisture and/or oxygen such as Al, Ba, Ca, Co, Cr, Fe, K, Li, Mg, Mn, Na, Ni, Sc, Sr, Ti, and V. Additionally, second metallic layer 80 includes a different metal than first metallic layer 70. It is preferred to have the second metallic layer 80 include a metal with a first ionization potential of less than 7 eV. Second metallic layer 80 can be deposited onto first metallic layer 40 by an evaporative method shortly before coating organic layer 90.

Coated donor element 31 can include a transferable layer for forming a useful layer in an OLED device, e.g. a hole-transporting material, a light-emitting material, an electron-transporting material, or some combination.

Hole-transporting materials useful in an OLED device are well known to include compounds such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. in U.S. Pat. No. 3,180,730. Other suitable triarylamines substituted with one or more vinyl radicals and/or comprising at least one active hydrogen-containing group are disclosed by Brantley et al. in U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. Such compounds include those represented by structural Formula A 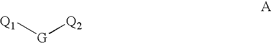
wherein:

Q₁ and Q₂ are independently selected aromatic tertiary amine moieties; and

G is a linking group such as an arylene, cycloalkylene, or alkylene group of a carbon-to-carbon bond.

In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural Formula A and containing two triarylamine moieties is represented by structural Formula B 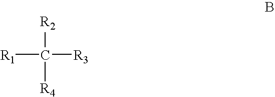
where:

R₁ and R₂ each independently represent a hydrogen atom, an aryl group, or an alkyl group or R₁ and R₂ together represent the atoms completing a cycloalkyl group; and

R₃ and R₄ each independently represent an aryl group, which is in turn substituted with a diaryl substituted amino group, as indicated by structural Formula C 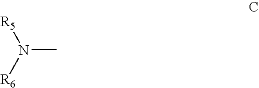
wherein R₅ and R₆ are independently selected aryl groups. In one embodiment, at least one of R₅ or R₆ contains a polycyclic fused ring structure, e.g., a naphthalene.

Another class of aromatic tertiary amines is the tetraaryldiamines. Desirable tetraaryldiamines include two diarylamino groups, such as indicated by Formula C, linked through an arylene group. Useful tetraaryldiamines include those represented by Formula D 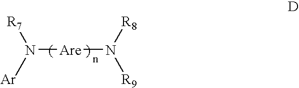
wherein:

each is an independently selected arylene group, such as a phenylene or anthracene moiety;

n is an integer of from 1 to 4; and

Ar, R₇, R₈, and R₉ are independently selected aryl groups.

In a typical embodiment, at least one of Ar, R₇, R₈, and R₉ is a polycyclic fused ring structure, e.g., a naphthalene.

The various alkyl, alkylene, aryl, and arylene moieties of the foregoing structural Formulae A, B, C, D, can each in turn be substituted. Typical substituents include alkyl groups, alkoxy groups, aryl groups, aryloxy groups, and halogens such as fluoride, chloride, and bromide. The various alkyl and alkylene moieties typically contain from 1 to about 6 carbon atoms. The cycloalkyl moieties can contain from 3 to about 10 carbon atoms, but typically contain five, six, or seven carbon atoms, e.g. cyclopentyl, cyclohexyl, and cycloheptyl ring structures. The aryl and arylene moieties are usually phenyl and phenylene moieties.

The hole-transporting layer in an OLED device can be formed of a single or a mixture of aromatic tertiary amine compounds. Specifically, one can employ a triarylamine, such as a triarylamine satisfying the Formula B, in combination with a tetraaryldiamine, such as indicated by Formula D. When a triarylamine is employed in combination with a tetraaryldiamine, the latter is positioned as a layer interposed between the triarylamine and the electron-injecting and transporting layer. Illustrative of useful aromatic tertiary amines are the following:
1,1-Bis(4-di-p-tolylaminophenyl)cyclohexane;
1,1-Bis(4-di-p-tolylaminophenyl)-4-phenylcyclohexane;
N,N,N′,N′-tetraphenyl-4,4′″-diamino-1,1′:4′,1″:4″,1′″-quaterphenyl;
Bis(4-dimethylamino-2-methylphenyl)phenylmethane;
1,4-bis[2-[4-[N,N-di(p-toly)amino]phenyl]vinyl]benzene (BDTAPVB);
N,N,N′,N′-Tetra-p-tolyl-4,4′-diaminobiphenyl;
N,N,N′,N′-Tetraphenyl-4,4′-diaminobiphenyl;
N,N,N′,N′-tetra-1-naphthyl-4,4′-diaminobiphenyl;
N,N,N′,N′-tetra-2-naphthyl-4,4′-diaminobiphenyl;
N-Phenylcarbazole;
4,4′-Bis[N-(1-naphthyl)-N-phenylamino]biphenyl (NPB);
4,4′-Bis[N-(1-naphthyl)-N-(2-naphthyl)amino]biphenyl (TNB);
4,4′-Bis[N-(1-naphthyl)-N-phenylamino]p-terphenyl;
4,4′-Bis[N-(2-naphthyl)-N-phenylamino]biphenyl;
4,4′-Bis[N-(3-acenaphthenyl)-N-phenylamino]biphenyl;
1,5-Bis[N-(1-naphthyl)-N-phenylamino]naphthalene;
4,4′-Bis[N-(9-anthryl)-N-phenylamino]biphenyl;
4,4′-Bis[N-(1-anthryl)-N-phenylamino]-p-terphenyl;
4,4′-Bis[N-(2-phenanthryl)-N-phenylamino]biphenyl;
4,4′-Bis[N-(8-fluoranthenyl)-N-phenylamino]biphenyl
4,4′-Bis[N-(2-pyrenyl)-N-phenylamino]biphenyl;
4,4′-Bis[N-(2-naphthacenyl)-N-phenylamino]biphenyl;
4,4′-Bis[N-(2-perylenyl)-N-phenylamino]biphenyl;
4,4′-Bis[N-(1-coronenyl)-N-phenylamino]biphenyl;
2,6-Bis(di-p-tolylamino)naphthalene;
2,6-Bis[di-(1-naphthyl)amino]naphthalene;
2,6-Bis[N-(1-naphthyl)-N-(2-naphthyl)amino]naphthalene;
N,N,N′,N′-Tetra(2-naphthyl)-4,4″-diamino-p-terphenyl;
4,4′-Bis {N-phenyl-N-[4-(1-naphthyl)-phenyl]amino}biphenyl;
2,6-Bis[N,N-di(2-naphthyl)amino]fluorene;
4,4′,4″-tris[(3-methylphenyl)phenylamino]triphenylamine (MTDATA); and
4,4′-Bis[N-(3-methylphenyl)-N-phenylamino]biphenyl (TPD).

Another class of useful hole-transporting materials includes polycyclic aromatic compounds as described in EP 1 009 041. Some hole-injecting materials described in EP 0 891 121 A1 and EP 1 029 909 A1 can also make useful hole-transporting materials. In addition, polymeric hole-transporting materials can be used such as poly(N-vinylcarbazole) (PVK), polythiophenes, polypyrrole, polyaniline, and copolymers such as poly(3,4-ethylenedioxythio-phene)/poly(4-styrenesulfonate) also called PEDOT/PSS.

Useful organic light-emitting materials are well known. As more fully described in U.S. Pat. Nos. 4,769,292 and 5,935,721, the light-emitting layers of the organic EL element comprise a luminescent or fluorescent material where electroluminescence is produced as a result of electron-hole pair recombination in this region. A light-emitting layer can be comprised of a single material, but more commonly includes a host doped with a guest compound or dopant where light emission comes primarily from the dopant. The host materials in the light-emitting layers can be an electron-transporting material, as defined below, a hole-transporting material, as defined above, or another material that supports hole-electron recombination. The dopant is usually chosen from highly fluorescent dyes, but phosphorescent compounds, e.g., transition metal complexes as described in WO 98/55561, WO 00/18851, WO 00/57676, and WO 00/70655 are also useful. Dopants are typically coated as 0.01 to 10% by weight into the host material.

The host and emitting materials can be small nonpolymeric molecules or polymeric materials including polyfluorenes and polyvinylarylenes, e.g., poly(p-phenylenevinylene), PPV. In the case of polymers, small molecule emitting materials can be molecularly dispersed into a polymeric host, or the emitting materials can be added by copolymerizing a minor constituent into a host polymer.

An important relationship for choosing an emitting material is a comparison of the bandgap potential which is defined as the energy difference between the highest occupied molecular orbital and the lowest unoccupied molecular orbital of the molecule. For efficient energy transfer from the host to the emitting material, a necessary condition is that the bandgap of the dopant is smaller than that of the host material. For phosphorescent emitters, including materials that emit from a triplet excited state, i.e. so called “triplet emitters”, it is also important that the triplet energy level of the host be high enough to enable energy transfer from host to emitting material.

Host and emitting molecules known to be of use include, but are not limited to, those disclosed in U.S. Pat. Nos. 4,768,292, 5,141,671, 5,150,006, 5,151,629, 5,294,870, 5,405,709, 5,484,922, 5,593,788, 5,645,948, 5,683,823, 5,755,999, 5,928,802, 5,935,720, 5,935,721; and 6,020,078.

Metal complexes of 8-hydroxyquinoline and similar derivatives (Formula E) constitute one class of useful host materials capable of supporting electroluminescence, and are particularly suitable for light emission of wavelengths longer than 500 nm, e.g., green, yellow, orange, and red 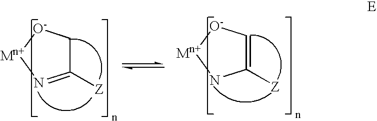
wherein:

M represents a metal;

n is an integer of from 1 to 3; and

Z independently in each occurrence represents the atoms completing a nucleus having at least two fused aromatic rings.

From the foregoing it is apparent that the metal can be a monovalent, divalent, or trivalent metal. The metal can, for example, be an alkali metal, such as lithium, sodium, or potassium; an alkaline earth metal, such as magnesium or calcium; or an earth metal, such as boron or aluminum. Generally any monovalent, divalent, or trivalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:
CO-1: Aluminum trisoxine [alias, tris(8-quinolinolato)aluminum(III)];
CO-2: Magnesium bisoxine [alias, bis(8-quinolinolato)magnesium(II)];
CO-3: Bis[benzo {f}-8-quinolinolato]zinc (II);
CO-4: Bis(2-methyl-8-quinolinolato)aluminum(III)-μ-oxo-bis(2-methyl-8-quinolinolato)aluminum(III);
CO-5: Indium trisoxine [alias, tris(8-quinolinolato)indium];
CO-6: Aluminum tris(5-methyloxine) [alias, tris(5-methyl-8-quinolinolato)aluminum(III)];
CO-7: Lithium oxine [alias, (8-quinolinolato)lithium(I)];
CO-8: Gallium oxine [alias, tris(8-quinolinolato)gallium(III)]; and
CO-9: Zirconium oxine [alias, tetra(8-quinolinolato)zirconium(IV)].

The host material in one or more of the light-emitting layers of this invention can be an anthracene derivative having hydrocarbon or substituted hydrocarbon substituents at the 9 and 10 positions. For example, derivatives of 9,10-di-(2-naphthyl)anthracene (Formula F) constitute one class of useful host materials capable of supporting electroluminescence, and are particularly suitable for light emission of wavelengths longer than 400 nm, e.g., blue, green, yellow, orange or red 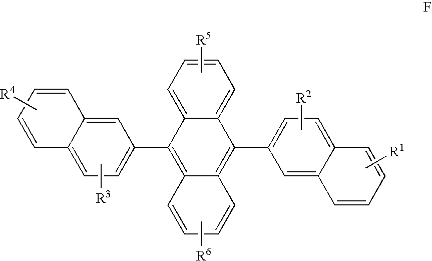
wherein R¹, R², R³, R⁴, R⁵, and R⁶ represent one or more substituents on each ring where each substituent is individually selected from the following groups:

Group 1: hydrogen, or alkyl of from 1 to 24 carbon atoms;

Group 2: aryl or substituted aryl of from 5 to 20 carbon atoms;

Group 3: carbon atoms from 4 to 24 necessary to complete a fused aromatic ring of anthracenyl, pyrenyl, or perylenyl;

Group 4: heteroaryl or substituted heteroaryl of from 5 to 24 carbon atoms as necessary to complete a fused heteroaromatic ring of furyl, thienyl, pyridyl, quinolinyl or other heterocyclic systems;

Group 5: alkoxylamino, alkylamino, or arylamino of from 1 to 24 carbon atoms; and

Group 6: fluorine, chlorine, bromine or cyano.

The monoanthracene derivative of Formula (I) is also a useful host material capable of supporting electroluminescence, and are particularly suitable for light emission of wavelengths longer than 400 nm, e.g., blue, green, yellow, orange or red. Anthracene derivatives of Formula (I) is described in commonly assigned U.S. patent application Ser. No. 10/693,121 filed Oct. 24, 2003 by Lelia Cosimbescu et al., entitled “Electroluminescent Device With Anthracene Derivative Host”, the disclosure of which is herein incorporated by reference, 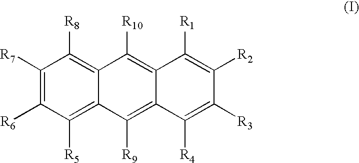
wherein:

R₁-R₈ are H; and

R₉ is a naphthyl group containing no fused rings with aliphatic carbon ring members; provided that R₉ and R₁₀ are not the same, and are free of amines and sulfur compounds. Suitably, R₉ is a substituted naphthyl group with one or more further fused rings such that it forms a fused aromatic ring system, including a phenanthryl, pyrenyl, fluoranthene, perylene, or substituted with one or more substituents including fluorine, cyano group, hydroxy, alkyl, alkoxy, aryloxy, aryl, a heterocyclic oxy group, carboxy, trimethylsilyl group, or an unsubstituted naphthyl group of two fused rings. Conveniently, R₉ is 2-naphthyl, or 1-naphthyl substituted or unsubstituted in the para position; and

R₁₀ is a biphenyl group having no fused rings with aliphatic carbon ring members. Suitably R₁₀ is a substituted biphenyl group, such that is forms a fused aromatic ring system including but not limited to a naphthyl, phenanthryl, perylene, or substituted with one or more substituents including fluorine, cyano group, hydroxy, alkyl, alkoxy, aryloxy, aryl, a heterocyclic oxy group, carboxy, trimethylsilyl group, or an unsubstituted biphenyl group. Conveniently, R₁₀ is 4-biphenyl, 3-biphenyl unsubstituted or substituted with another phenyl ring without fused rings to form a terphenyl ring system, or 2-biphenyl. Particularly useful is 9-(2-naphthyl)-10-(4-biphenyl)anthracene.

Another useful class of anthracene derivatives is represented by general formula (II):
A 1-L-A 2 (II)
wherein A 1 and A 2 each represent a substituted or unsubstituted monophenylanthryl group or a substituted or unsubstituted diphenylanthryl group and can be the same with or different from each other and L represents a single bond or a divalent linking group.

Another useful class of anthracene derivatives is represented by general formula (III):
A 3-An-A 4 (III)
wherein An represents a substituted or unsubstituted divalent anthracene residue group, A 3 and A 4 each represent a substituted or unsubstituted monovalent condensed aromatic ring group or a substituted or unsubstituted non-condensed ring aryl group having 6 or more carbon atoms and can be the same with or different from each other. Specific examples of useful anthracene materials for use in a light-emitting layer include:

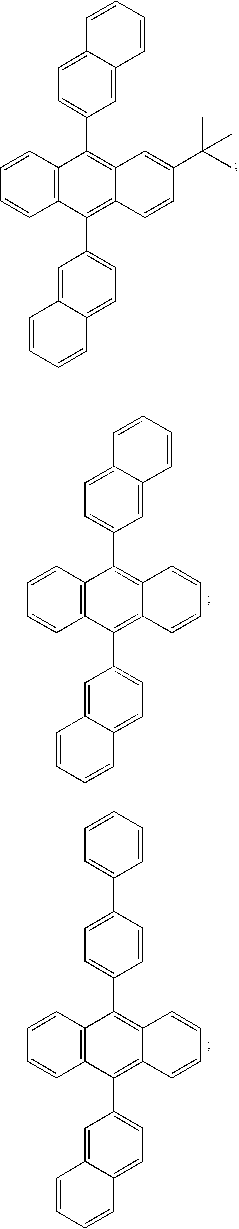

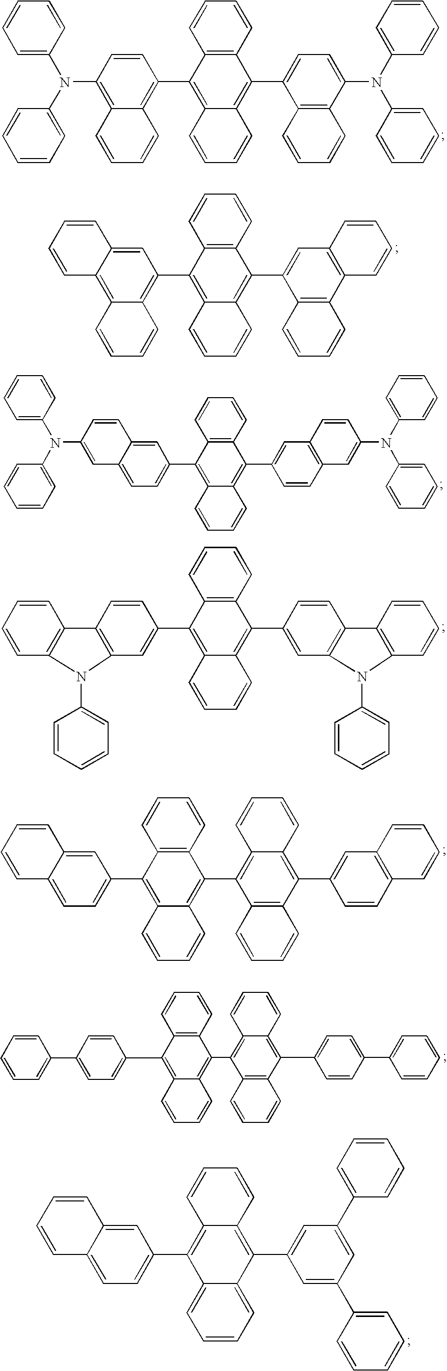

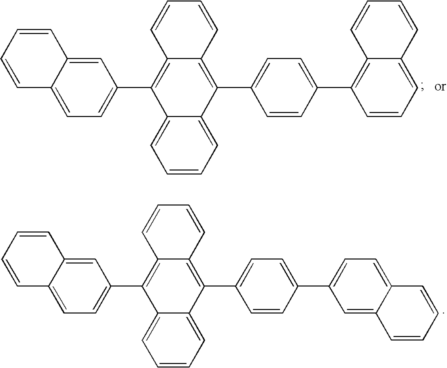

Benzazole derivatives (Formula G) constitute another class of useful host materials capable of supporting electroluminescence, and are particularly suitable for light emission of wavelengths longer than 400 nm, e.g., blue, green, yellow, orange or red 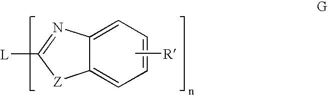
where:

n is an integer of 3 to 8;

Z is O, NR or S;

R′ is hydrogen; alkyl of from 1 to 24 carbon atoms, for example, propyl, t-butyl, heptyl, and the like; aryl or heteroatom-substituted aryl of from 5 to 20 carbon atoms for example phenyl, naphthyl, furyl, thienyl, pyridyl, quinolinyl and other heterocyclic systems; or halo such as chloro, fluoro; or atoms necessary to complete a fused aromatic ring; and

L is a linkage unit including alkyl, aryl, substituted alkyl, or substituted aryl, which conjugately or unconjugately connects the multiple benzazoles together.

An example of a useful benzazole is 2,2′,2″-(1,3,5-phenylene)-tris[1-phenyl-1H-benzimidazole].

Certain of the hole-transporting materials described above, e.g. 4,4′-bis[N-(1-naphthyl)-N-phenylamino]biphenyl and 4,4′-bis[N-(2-naphthyl)-N-phenylamino]biphenyl, can also be useful hosts for one or more of the light-emitting layers of this invention.

Suitable host materials for phosphorescent emitters, including materials that emit from a triplet excited state, i.e. so called “triplet emitters”, should be selected so that the triplet exciton can be transferred efficiently from the host material to the phosphorescent material. For this transfer to occur, it is a highly desirable condition that the excited state energy of the phosphorescent material be lower than the difference in energy between the lowest triplet state and the ground state of the host. However, the band gap of the host should not be chosen so large as to cause an unacceptable increase in the drive voltage of the OLED. Suitable host materials are described in WO 00/70655 A2, 01/39234 A2, 01/93642 A1, 02/074015 A2, 02/15645 A1, and U.S. Patent Application Publication 2002/0117662 A1. Suitable hosts include certain aryl amines, triazoles, indoles and carbazole compounds. Examples of desirable hosts are 4,4′-N,N′-dicarbazole-biphenyl (CBP), 2,2′-dimethyl-4,4′-(N,N′-dicarbazole)biphenyl, m-(N,N′-dicarbazole)benzene, and poly(N-vinylcarbazole), including their derivatives.

Desirable host materials are capable of forming a continuous film. The light-emitting layer can contain more than one host material in order to improve the device's film morphology, electrical properties, light emission efficiency, and lifetime. The light-emitting layer can contain a first host material that has effective hole-transporting properties, and a second host material that has effective electron-transporting properties.

Desirable fluorescent dopants for OLED displays commonly include perylene or derivatives of perylene, derivatives of anthracene, tetracene, xanthene, rubrene, coumarin, rhodamine, quinacridone, dicyanomethylenepyran compounds, thiopyran compounds, polymethine compounds, pyrilium and thiapyrilium compounds, derivatives of distryrylbenzene or distyrylbiphenyl, bis(azinyl)methane boron complex compounds, and carbostyryl compounds. Illustrative examples of dopants include, but are not limited to, the following:

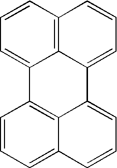

L1

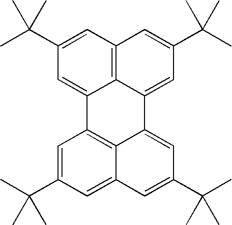

L2

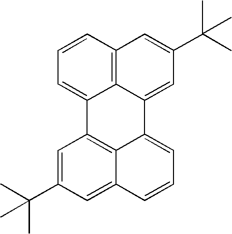

L3

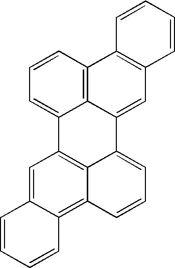

L4

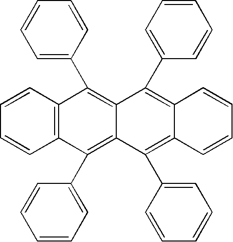

L5

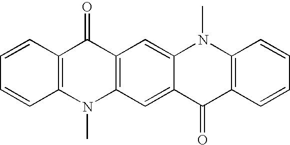

L6

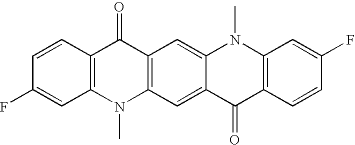

L7

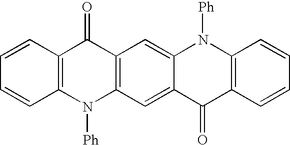

L8

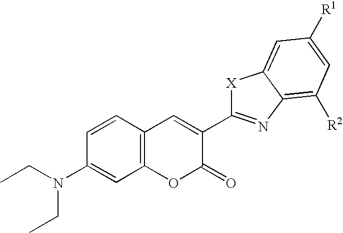

| | X | R1 | R2 |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl |

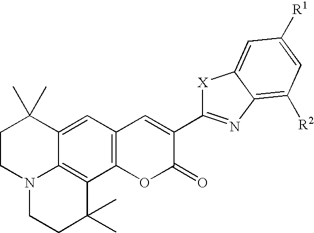

| | X | R1 | R2 |
|---|---|---|---|
| L23 | O | H | H |
| L24 | O | H | Methyl |
| L25 | O | Methyl | H |
| L26 | O | Methyl | Methyl |
| L27 | O | H | t-butyl |
| L28 | O | t-butyl | H |
| L29 | O | t-butyl | t-butyl |
| L30 | S | H | H |
| L31 | S | H | Methyl |
| L32 | S | Methyl | H |
| L33 | S | Methyl | Methyl |
| L34 | S | H | t-butyl |
| L35 | S | t-butyl | H |
| L36 | S | t-butyl | t-butyl |

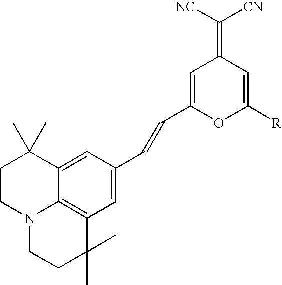

| | R |
|---|---|
| L37 | phenyl |
| L38 | methyl |
| L39 | t-butyl |
| L40 | mesityl |

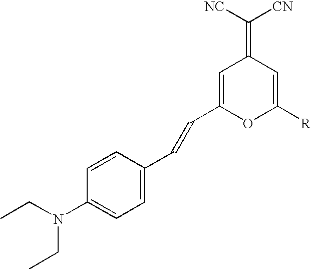

| | R |
|---|---|
| L41 | phenyl |
| L42 | methyl |
| L43 | t-butyl |
| L44 | mesityl |

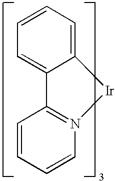

L45

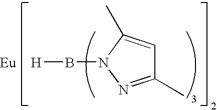

L46

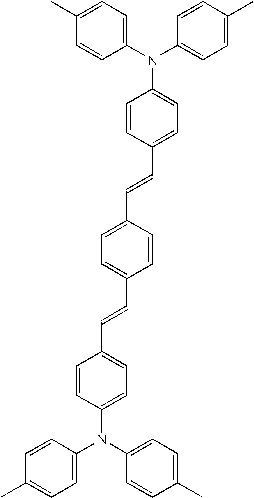

L47

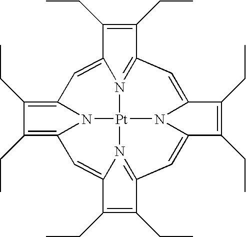

L48

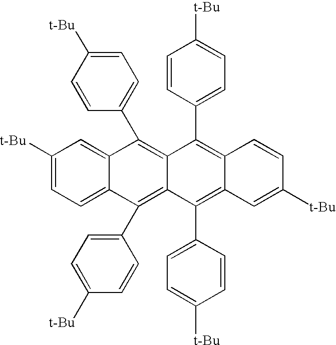

L49

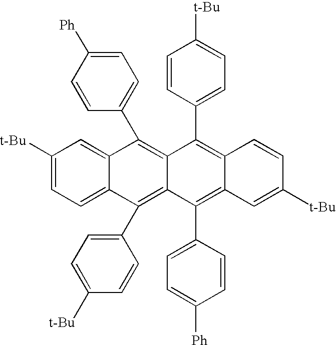

L50

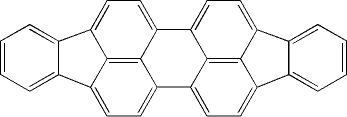

L51

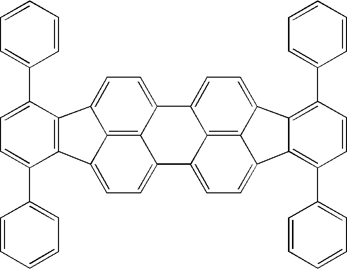

L52

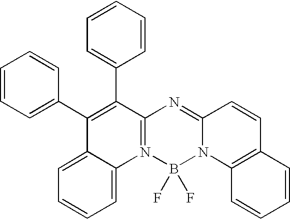

L53

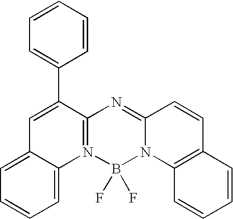

L54

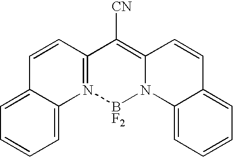

L55

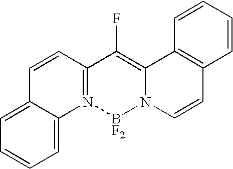

L56.

Other organic emissive materials can be polymeric substances, e.g. polyphenylenevinylene derivatives, dialkoxy-polyphenylenevinylenes, poly-para-phenylene derivatives, and polyfluorene derivatives, as taught by Wolk et al. in commonly assigned U.S. Pat. No. 6,194,119 and references cited therein.

Examples of useful phosphorescent materials that can be used in light-emitting layers of this invention include, but are not limited to, those described in WO 00/57676; WO 00/70655; WO 01/41512 A1; WO 02/15645 A1; U.S. Patent Application Publication 2003/0017361 A1; WO 01/93642 A1; WO 01/39234 A2; U.S. Pat. No. 6,458,475; WO 02/071813 A1; U.S. Pat. No. 6,573,651; U.S. Patent Application Publication 2002/0197511 A1; WO 02/074015 A2; U.S. Pat. No. 6,451,455 B1; U.S. Patent Application Publications 2003/0072964 A1 and 2003/0068528 A1; U.S. Pat. Nos. 6,413,656, 6,515,298, 6,451,415, and 6,097,147; U.S. Patent Application Publications 2003/0124381 A1, 2003/0059646 A1, and 2003/0054198 A1; EP 1 239 526 A2; EP 1 238 981 A2; EP 1 244 155 A2; U.S. Patent Application Publications 2002/0100906 A1, 2003/0068526 A1, and 2003/0068535 A1; JP 2003/073387A; JP 2003/073388A; U.S. Patent Application Publications 2003/0141809 A1 and 2003/0040627 A1; JP 2003/059667A; JP 2003/073665A; and U.S. Patent Application Publication 2002/0121638 A1.

The emission wavelengths of cyclometallated Ir(III) complexes of the type IrL₃ and IrL₂L′, such as the green-emitting fac-tris(2-phenylpyridinato-N,C^{2′})Iridium(III) and bis(2-phenylpyridinato-N,C^{2′})Iridium(III)(acetylacetonate), can be shifted by substitution of electron donating or withdrawing groups at appropriate positions on the cyclometallating ligand L, or by choice of different heterocycles for the cyclometallating ligand L. The emission wavelengths can also be shifted by choice of the ancillary ligand L′. Examples of red emitters are the bis(2-(2′-benzothienyl)pyridinato-N,C^{3′})Iridium(III)(acetylacetonate) and tris(1-phenylisoquinolinato-N,C)Iridium(III). A blue-emitting example is bis(2-(4,6-diflourophenyl)-pyridinato-N,C^{2′})Iridium(III)(picolinate).

Red electrophosphorescence has been reported, using bis(2-(2′-benzo[4,5-a]thienyl)pyridinato-N, C³) iridium (acetylacetonate) [Btp₂Ir(acac)] as the phosphorescent material, in Adachi, C., Lamansky, S., Baldo, M. A., Kwong, R. C., Thompson, M. E., and Forrest, S. R., App. Phys. Lett., 78, 1622-1624 (2001).

Still other examples of useful phosphorescent materials include coordination complexes of the trivalent lanthanides such as Tb³⁺ and Eu³⁺ in J. Kido et al., Appl. Phys. Lett., 65, 2124 (1994).

Preferred electron-transporting materials are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural Formula E, previously described.

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural Formula G are also useful electron-transporting materials. Related materials, denoted collectively as BAlq, can also be used as electron transporting materials. Bryan et al., in U.S. Pat. No. 5,141,671, discuss such materials. The BAlq compounds are mixed-ligand aluminum chelates, specifically bis(Rₛ-8-quinolinolato)(phenolato)aluminum(III) chelates, where Rₛ is a ring substituent of the 8-quinolinolato ring nucleus. These compounds are represented by the formula (RₛQ)₂AlOL, where Q represents a substituted 8-quinolinolato ligand, Rₛ represents an 8-quinolinolato ring substituent to block sterically the attachment of more than two substituted 8-quinolinolato ligands to the aluminum ion, OL is phenolato ligand, O is oxygen, and L is phenyl or a hydrocarbon-substituted phenyl moiety of from 6 to 24 carbon atoms. These materials also make effective hole- or exciton-blocking layers for use with triplet emitting materials, as is known in the art.

Other electron-transporting materials can be polymeric substances, e.g. polyphenylenevinylene derivatives, poly-para-phenylene derivatives, polyfluorene derivatives, polythiophenes, polyacetylenes, and other conductive polymeric organic materials.

The donor support must be capable of maintaining the structural integrity during the light-to-heat-induced transfer step while pressurized on one side, and during any preheating steps contemplated to remove volatile constituents such as water vapor. Additionally, the donor support must be capable of receiving on one surface a relatively thin coating of organic donor material, and of retaining this coating without degradation during anticipated storage periods of the coated support. Support materials meeting these requirements include, for example, metal foils, certain plastic foils which exhibit a glass transition temperature value higher than a support temperature value anticipated to cause transfer of the transferable organic donor materials of the coating on the support, and fiber-reinforced plastic foils. Some examples include polyimide, polysulfone, polyetherimide, polyvinylidinefluoride or polymethylpentene, or mixtures thereof. While selection of suitable support materials can rely on known engineering approaches, it will be appreciated that certain aspects of a selected support material merit further consideration when configured as a donor support useful in the practice of the invention. For example, the support can require a multistep cleaning and surface preparation process prior to precoating with transferable organic material. For this invention, it is most useful if the transparent support is less than 200 micrometers thick.

Substrate 42 can be an organic solid, an inorganic solid, or include organic and inorganic solids that provides a surface for receiving the light-emitting material from a donor. Substrate 42 can be rigid or flexible and can be processed as separate individual pieces, such as sheets or wafers, or as a continuous roll. Typical materials include glass, plastic, metal, ceramic, semiconductor, metal oxide, semiconductor oxide, semiconductor nitride, or combinations thereof. Substrate 42 can be a homogeneous mixture of materials, a composite of materials, or multiple layers of materials. Substrate 42 can be a substrate that is commonly used for preparing OLED devices, e.g. active-matrix low-temperature polysilicon TFT substrate. The substrate 42 can either be light transmissive or opaque, depending on the intended direction of light emission. The light transmissive property is desirable for viewing the EL emission through the substrate 42. Transparent glass or plastic are commonly employed in such cases. For applications where the EL emission is viewed through the top electrode, the transmissive characteristic of the bottom support is immaterial, and therefore can be light transmissive, light-absorbing or light reflective. Substrate 42 for use in this case include, but are not limited to, glass, plastic, semiconductor materials, ceramics, and circuit board materials.

The invention and its advantages can be better appreciated by the following comparative examples.

Coated Donor Element Example

A coated donor element for use in the inventive examples of OLED devices was constructed in the following manner:
1. An antireflection layer of 40 nm of silicon, an absorption layer of 40 nm of chromium, and a layer of 15 nm of aluminum were vacuum-deposited in that order onto a 51 micron polyimide donor element.
2. A mixed donor layer was formed over the aluminum by co-evaporating 20 nm of 2-tert-butyl-9,10-bis(2-naphthyl)anthracene (TBADN) and 0.25 nm of tetra-tert-butyl-perylene (TBP) under vacuum from separate evaporating boats.
   OLED Device Example 1 (Control Device Example)

A controlled OLED device was constructed in the following manner by vapor deposition process:
1. Onto a clean glass receiver element, a pattern of 40 to 80 nm transparent electrodes was created by a standard photolithography process.
2. The resulting surface was treated with a plasma oxygen etch, followed by plasma deposition of ˜0.1 nm of CFₓ.
3. A 150 nm hole-transporting layer of 4,4′-bis[N-(1-naphthyl)-N-phenylamino]biphenyl (NPB) was vacuum deposited onto the surface.
4. A mixed emission layer was formed over the hole-transporting layer by co-evaporating 20 nm of 2-tert-butyl-9,10-bis(2-naphthyl)anthracene (TBADN) and 0.25 nm of tetra-tert-butyl-perylene (TBP) under vacuum from separate evaporating boats.
5. A 30 nm electron-transporting layer of tris(8-hydroxyquinoline)aluminum (ALQ) was vacuum deposited onto the emissive layer.
6. A 0.5 nm electron-injecting layer of LiF was vacuum-deposited onto the electron-transporting layer.
7. An electrode was formed over the electron-injecting layer by depositing 100 nm aluminum by vacuum deposition.
   OLED Device Example 2 (Inventive Example)
1. Onto a clean glass receiver element, a pattern of 40 to 80 nm transparent electrodes was created by a standard photolithography process.
2. The resulting surface was treated with a plasma oxygen etch, followed by plasma deposition of ˜0.1 nm of CFₓ.
3. A 150 nm hole-transporting layer of 4,4′-bis[N-(1-naphthyl)-N-phenylamino]biphenyl (NPB) was vacuum deposited onto the surface.
4. Moving the coated donor element to a transfer position with argon gas to provide a pressure difference of 4.7 PSI applied between the bottom and top surfaces of the coated donor element, and the time from coating the donor element to after the pressure difference has been applied between the bottom and top surfaces of the coated donor element was 12 minutes.
5. In regions of the receiver element in which emission is desired, transfer of the organic layer from the coated donor element was effected by irradiation through the polyimide support with an infrared multichannel linear laser light beam. The beam was scanned in a direction perpendicular to the long dimension of the beam at a velocity of 650 mm/sec. The dwell time was 13 microseconds with an energy density of 0.3 J/cm²
6. A 30 nm electron-transporting layer of tris(8-hydroxyquinoline)aluminum (ALQ) was vacuum deposited onto the emissive layer.
7. A 0.5 nm electron-injecting layer of LiF was vacuum-deposited onto the electron-transporting layer.
8. An electrode was formed over the electron-injecting layer by depositing 100 nm aluminum by vacuum deposition.
   OLED Device Example 3 (Inventive Example)

An OLED device satisfying the requirements of this invention was constructed as in Example 2, except that the time from coating the donor element to after the pressure difference has been applied between the bottom and top surfaces of the coated donor element was 37 minutes.

OLED Device Example 4 (Inventive Example)

An OLED device satisfying the requirements of this invention was constructed as in Example 2, except that the time from coating the donor element to after the pressure difference has been applied between the bottom and top surfaces of the coated donor element was 760 minutes.

OLED Device Example 5 (Inventive Example)

1. Onto a clean glass receiver element, a pattern of 40 to 80 nm transparent electrodes was created by a standard photolithography process.
2. The resulting surface was treated with a plasma oxygen etch, followed by plasma deposition of ˜0.1 nm of CFₓ.
3. A 150 nm hole-transporting layer of 4,4′-bis[N-(1-naphthyl)-N-phenylamino]biphenyl (NPB) was vacuum deposited onto the surface.
4. Moving the coated donor element to a transfer position with argon gas to provide pressure difference of 4.7 PSI between the bottom and top surfaces of the coated donor element.
5. In regions of the receiver element in which emission is desired, transfer of the emissive material from the coated donor element was effected by irradiation through the polyimide support with an infrared multichannel linear laser light beam. The beam was scanned in a direction perpendicular to the long dimension of the beam at a velocity of 650 mm/sec. The dwell time was 13 microseconds with an energy density of 0.3 J/cm²
6. The time from pressure difference has been applied to end of radiation transfer process was 6 minutes.
7. A 30 nm electron-transporting layer of tris(8-hydroxyquinoline)aluminum (ALQ) was vacuum deposited onto the emissive layer.
8. A 0.5 nm electron-injecting layer of LiF was vacuum-deposited onto the electron-transporting layer.
9. An electrode was formed over the electron-injecting layer by depositing 100 nm aluminum by vacuum deposition.
   OLED Device Example 6 (Inventive Example)

An OLED device satisfying the requirements of this invention was constructed as in Example 5, except that the time from pressure difference has been applied to end of radiation transfer process was 18 minutes.

OLED Device Example 7 (Inventive Example)

An OLED device satisfying the requirements of this invention was constructed as in Example 5, except that the pressure difference of 0.7 PSI was applied between the bottom and top surfaces of the coated donor element.

OLED Device Example 8 (Inventive Example)

An OLED device satisfying the requirements of this invention was constructed as in Example 5, except that the pressure difference of 0.7 PSI was applied between the bottom and top surfaces of the coated donor element and the time from pressure difference has been applied between the bottom and top surfaces of the coated donor element to end of radiation transfer process was 18 minutes.

The relative lifetime was measured by putting a constant current of 80 mA/cm² through the constructed inventive and comparative OLED devices and monitoring the intensity of the light output with time. The relative time to 50% luminance was calculated by dividing the inventive OLED device time to 50% luminance by the controlled OLED device time to 50% luminance. The blue dopant emission was detected by observing the emission spectra for the characteristic 3-peaked emission from TBP, with the strongest peak located at about 460 nm. The results of Examples 1 to 4 are shown in Table 1.

TABLE 1

| | | Selected | | Time from coating | |
|---|---|---|---|---|---|
| | | pressure | | donor to applied | Relative Time |
| | Example | difference | Environmental | pressure difference | to 50% |
| Example # | Type | (PSI) | Conditions | (minutes) | Luminance |
| 1 | Control | N/A | Controlled | N/A | 1 |
| 2 | Inventive | 4.7 | Controlled | 12 | 0.96 |
| 3 | Inventive | 4.7 | Controlled | 37 | 0.82 |
| 4 | Inventive | 4.7 | Controlled | 760 | 0.54 |

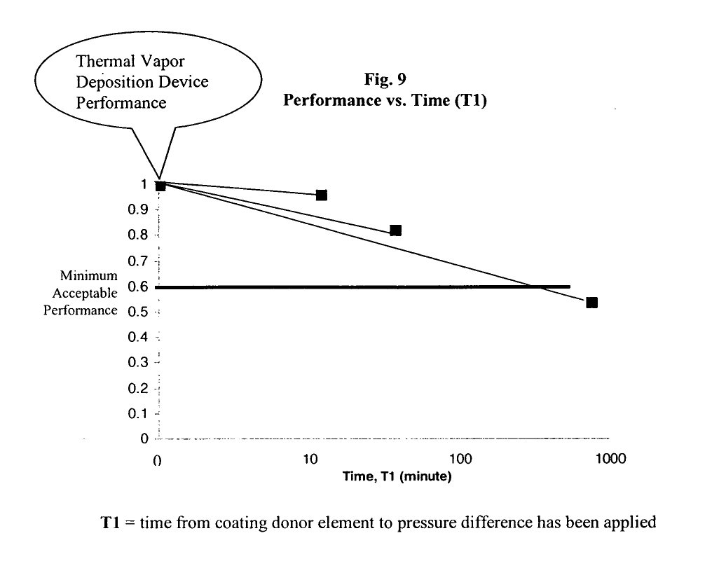

The results of Examples 1 to 4 can also be presented in a graphical form as FIG. 9

The results of Examples 1 to 4 above demonstrate that storage time of coated donor elements at environmental conditions in the vacuum chamber have a large impact on the lifetime of the OLED device, where lifetime is defined as the time for the luminance to decrease to 50% of the initial value. The results also show the first selected time from coating donor to pressure difference has been applied between the bottom and top surfaces of the coated donor element should be shorter in order to obtain good lifetime for the OLED device. The results show that the first selected time should be less than 500 minutes and most preferably less than 37 minutes to achieve accepatble device performance of at least 60% and 80% of the lifetime of a thermal vapor deposition OLED device, respectively, in typical OLED high vacumm equipment.

The results of Examples 5 to 8 are shown in Table 2.

TABLE 2

| | | | Time from pressure | |
|---|---|---|---|---|
| | | Selected | has been applied to | |
| | | pressure | end of radiation | Relative |
| | Example | difference | transfer process | Time to 50% |
| Example # | Type | (PSI) | (minutes) | Luminance |
| 1 | Control | N/A | N/A | 1 |
| 5 | Inventive | 4.7 | 6 | 0.8 |
| 6 | Inventive | 4.7 | 18 | 0.3 |
| 7 | Inventive | 0.7 | 6 | 1.1 |
| 8 | Inventive | 0.7 | 18 | 1.0 |

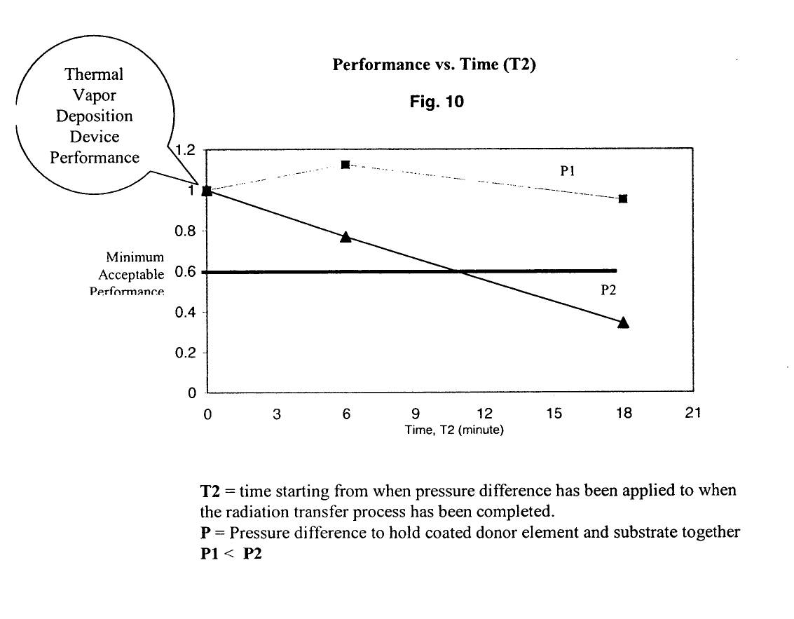

The results of Examples 5 to 8 also presented in a graphical form as FIG. 10

The results from Examples 5 to 8 demonstrate that selecting the pressure difference and/or time from when pressure difference has been applied to the end of the radiation transfer process can result in OLED devices made by radiation transfer having relative time to 50% luminance that are comparable to standard thermal vapor deposition OLED devices. The results show that for selected pressure differences greater than 0.7 PSI, the second selected time from when pressure difference has been applied to the end of the radiation transfer process should be less than 18 minutes and preferably less than 6 minutes. The results also show that for selected pressure differences less than or equal to 0.7 PSI, the second selected time from when pressure difference has been applied to the end of the radiation transfer process may be longer than 18 minutes. The preferred selected pressure difference is less than or equal to 4.7 PSI and the most preferred pressure difference is less than or equal to 0.7 PSI. This invention allows OLED devices to be patterned by radiation thermal transfer and maintain physical properties equal to OLED devices deposited by standard thermal vapor deposition means.

The invention has been described in detail with particular reference to certain preferred embodiments thereof, but it will be understood that variations and modifications can be effected within the spirit and scope of the invention.

### PARTS LIST

10 vacuum coater
12 vacuum pump
13 second fixture
14 load lock
15 plate
16 load lock
17 machined slot
20 coating station
22 transfer station
23 gasket
24 gasket
25 controlled environment
28 retaining clamp
29 rigid frame
30 donor element
31 coated donor element
32 donor support
33 bottom surface of coated donor element
34 coating apparatus
35 top surface of coated donor element
36 transfer apparatus
37 first fixture
38 laser
39 base plate
40 laser beam
42 substrate
43 fluid inlet
44 pressure chamber
45 first chamber
46 transparent portion
49 fluid supply
48 channel
50 transparent support
51 fluid passage
60 antireflection layer
70 first metallic layer
80 second metallic layer
90 organic layer
E environmental contamination condition
E1, E2, E3 different environmental contamination conditions
T1 time between coating donor element and a selected pressure
difference has been applied.
P pressure difference
P1, P2, P3 different selected pressure difference
C1, C2 different contamination conditions
T2 Time from gas pressure has been applied to end of radiation transfer process.
TE1, tE2, tE3 maximum selected time for different environments

1. In a method of making a device including forming an organic layer over a substrate, comprising:
(a) providing a donor element having top and bottom surfaces and coating the top surface of the donor element with organic material;
(b) moving the coated donor element to a transfer position in relation to the substrate in a controlled environment; and
(c) selecting a pressure difference at the transfer position between the top and bottom surfaces of the donor element to maintain a spaced position between the top surface of the donor element and the substrate wherein the selected pressure difference is such that the performance of the device is within an acceptable range.

2. The method of claim 1 further including:
(d) applying radiation after the pressure difference has been applied within a selected time to transfer organic material to the substrate wherein the selected time is such that the performance of the device is within an acceptable range.

3. The method of claim 1 wherein contamination in the controlled environment is reduced to improve the performance of the device.

4. In a method of making a device including forming an organic layer over a substrate, comprising:
(a) providing a donor element having top and bottom surfaces and coating the top surface of the donor element with organic material; and
(b) moving the coated donor element to a transfer position in a controlled environment within a first selected time, and wherein the first selected time is such that the performance of the device is within an acceptable range.

5. The method of claim 4 wherein contamination in the controlled environment is reduced to improve the performance of the device.

6. The method of claim 4 further including
(c) Selecting a pressure difference at the transfer position between the top and bottom surfaces of the coated donor element to maintain a spaced position between the top surface of the coated donor element and the substrate wherein the selected pressure difference is such that the performance of the device is within an acceptable range.

7. The method of claim 6 further including:
(d) applying radiation after the pressure difference has been applied within a second selected time to transfer organic material to the receiver element wherein the second selected time is such that the performance of the device is within an acceptable range.

8. In a method of making a device including forming an organic layer over a substrate, comprising:
(a) providing a donor element having top and bottom surfaces and coating the top surface of the donor element with organic material;
(b) moving the coated donor element to a transfer position in relation to the substrate in a controlled environment; and
(c) selecting a pressure difference in a range of greater than 0 and less than or equal to 4.7 PSI at the transfer position between the top and bottom surfaces of the donor element.

9. The method of claim 8 further including:
(d) applying radiation after the pressure difference has been applied within a time selected between greater than 0 and less than 18 minutes to transfer organic material to the substrate.

10. The method of claim 1 wherein the device is an OLED device.

11. The method of claim 4 wherein the device is an OLED device.

12. The method of claim 8 wherein the device is an OLED device.

13. The method of claim 8 wherein the selected pressure difference is greater than 0 and less than or equal to 0.7 PSI.

14. The method of claim 9 wherein the selected time is greater than 0 and less than 6 minutes.

15. The method of claim 4 wherein the first selected time is greater than 0 and less than 500 minutes.

16. The method of claim 4 wherein the selected time is greater than 0 and less than 37 minutes.

17. The method of claim 6 wherein the selected pressure difference is greater than 0 and less than or equal to 4.7 PSI.

18. The method of claim 6 wherein the selected pressure difference is greater than 0 and less than or equal to 0.7 PSI.
